(19) United States
(12) Patent Application Publication
(10) Pub. No.: US 2007/0018312 A1
(43) Pub. Date: Jan. 25, 2007

(54) Wiring substrate and semiconductor package implementing the same

(76) Inventor: Sang-Gui Jo, Asan-si (KR)

Correspondence Address: HARNESS, DICKEY & PIERCE, P.L.C., P.O. BOX 8910, RESTON, VA, 20195, US

(21) Appl. No.: 11/303,916

(22) Filed: Dec. 19, 2005

(30) Foreign Application Priority Data
Jul. 20, 2005 (KR) 2005-65905

(51) Int. Cl. H01L 23/34

(52) U.S. Cl. 257/720

(57) ABSTRACT

A wiring substrate may have a first surface including a chip mounting pad, and a second surface opposite to the first surface. A heat radiating layer may be provided on the second surface of the wiring substrate. A plurality of heat conducting elements may connect the chip mounting pad to the heat radiating layer. Metal protrusions may be provided on the chip mounting pad and may directly contact a semiconductor chip.

### PRIORITY STATEMENT

This U.S. non-provisional application claims benefit of priority under 35 U.S.C. § 119 from Korean Patent Application No. 2005-65905, filed on Jul. 20, 2005, the entire contents of which are incorporated herein by reference.

### BACKGROUND

1. Field of the Invention

Example embodiments of the present invention relate to a wiring substrate and a semiconductor package implementing the wiring substrate.

2. Description of the Related Art

Semiconductor chips may be packaged using various techniques. Semiconductor packages may protect the semiconductor chips and may provide an electrical connection between the semiconductor chip and an external circuit board, for example.

Numerous and varied semiconductor packages are well known in this art. Typically (but certainly not in all cases), plastic packages may implement lead frames to provide an electrical connection between a semiconductor chip and an external circuit board. Typically (but certainly not in all cases), ball grid array (BGA) packages may implement printed circuit boards having circuit wirings and solder bumps, instead of lead frames. As compared to plastic packages, BGA packages may have a reduced mounting area and improved electrical characteristics, for example.

In BGA packages, heat from a semiconductor chip may be radiated through solder bumps and/or package surfaces. For further heat radiation, a heat spreader 80 may be implemented as shown in FIG. 1.

A conventional BGA package 100 may include a wiring substrate 10 and a semiconductor chip 20. The semiconductor chip 20 may be provided on the wiring substrate 10 using a first adhesive 30. Bonding wires 40 may electrically connect the semiconductor chip 20 to the wiring substrate 10. An encapsulant 50 may be provided to protect and/or seal (for example) the semiconductor chip 20 and the bonding wires 40. Solder bumps 60 may be provided on the lower surface of the wiring substrate 10. A heat spreader 80 may be provided on the encapsulant 50 using a second adhesive 70.

The heat spreader 80 may radiate heat, which may be generated during the operation of the semiconductor chip 10, to the external environment.

Although the conventional BGA package 100 may generally provide acceptable performance, it is not without shortcomings. For example, the encapsulant 50 may be fabricated from a molding compound that may have relatively low heat conductivity. Accordingly, the heat radiation through the heat spreader 80 mounted on the encapsulant 50 may be relatively inefficient.

The heat spreader 80 may increase the thickness of the BGA package 100, thereby making it difficult to achieve a thin BGA package. Further, the productivity of the BGA package 100 may be reduced while the manufacturing cost may be increased.

### SUMMARY

According to an example, non-limiting embodiments, a wiring substrate may include a substrate body having a first surface and a second surface opposite to the first surface. A metal wiring layer may be provided on the first surface of the substrate body. The metal wiring layer may have a chip mounting pad, a plurality of substrate pads, and a plurality of terminal pads connected to the substrate pads. A metal heat radiating layer may be provided on the second surface of the substrate body. A plurality of heat conducting elements may penetrate the substrate body to connect the chip mounting pad to the heat radiating layer.

According to another example, non-limiting embodiment, a semiconductor package may include a semiconductor chip having an active surface supporting a plurality of chip pads. A wiring substrate may include a substrate body having a first surface and a second surface opposite to the first surface. A metal wiring layer may be provided on the first surface of the substrate body. The metal wiring layer may have a chip mounting pad, a plurality of substrate pads, and a plurality of terminal pads connected to the substrate pads. A metal heat radiating layer may be provided on the second surface of the substrate body. A plurality of heat conducting elements may penetrate the substrate body to connect the chip mounting pad to the heat radiating layer. Bonding wires may electrically connect the semiconductor chip to the wiring substrate. An encapsulant may seal the semiconductor chip and the bonding wires. External connection terminals may be provided on the terminal pads.

According to another example, non-limiting embodiment, a semiconductor package may include a semiconductor chip. A wiring substrate may have a first surface including a chip mounting pad on which the semiconductor chip is provided, a second surface having a heat radiating layer, and heat conducting elements extending between the heat radiating layer and the semiconductor chip. External connection terminals may be provided on the first surface of the wiring substrate.

### BRIEF DESCRIPTION OF THE DRAWINGS

Example, non-limiting embodiments of the present invention will be readily understood with reference to the following detailed description thereof provided in conjunction with the accompanying drawings, wherein like reference numerals designate like structural elements.

FIG. 1 is a cross-sectional view of a conventional BGA package having a heat spreader.

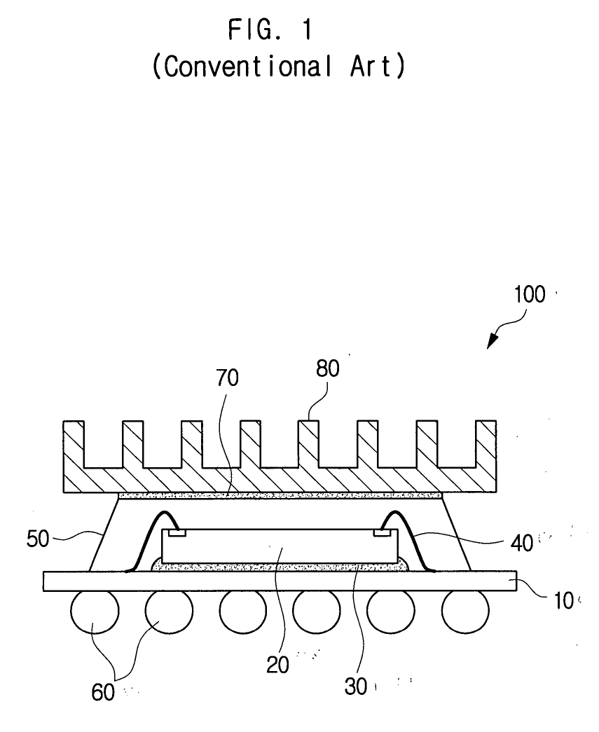

FIG. 2 is a perspective view of a wiring substrate in accordance with an example, non-limiting embodiment of the present invention.

FIG. 3 is a cross-sectional view taken along the line III-III of FIG. 2.

FIG. 4 is a cross-sectional view of a semiconductor package that may implement the wiring substrate of FIGS. 2 and 3 in accordance with an example, non-limiting embodiment of the present invention.

FIG. 5 is a perspective view of a wiring substrate in accordance with another example, non-limiting embodiment of the present invention.

FIG. 6 is a cross-sectional view taken along the line VI-VI of FIG. 5.

FIG. 7 is a cross-sectional view of a semiconductor package that may implement the wiring substrate of FIGS. 5 and 6 in accordance with another example, non-limiting embodiment of the present invention.

FIG. 8 is a cross-sectional view of a semiconductor package that may implement a wiring substrate in accordance with another example, non-limiting embodiment of the present invention.

The drawings are for illustrative purposes only and are not drawn to scale. The spatial relationships and relative sizing of the elements illustrated in the various embodiments may have been reduced, expanded and/or rearranged to improve the clarity of the figures with respect to the corresponding description. The figures, therefore, should not be interpreted as accurately reflecting the relative sizing and/or positioning of the corresponding structural elements that could be encompassed by an actual device manufactured according to the example, non-limiting embodiments of the invention.

### DETAILED DESCRIPTION OF EXAMPLE, NON-LIMITING EMBODIMENTS

Example, non-limiting embodiments of the present invention will be described more fully with reference to the accompanying drawings. This invention may, however, be embodied in many different forms and should not be construed as limited to the example embodiments set forth herein. Rather, the disclosed embodiments are provided so that this disclosure will be thorough and complete, and will fully convey the scope of the invention to those skilled in the art. The principles and features of this invention may be employed in varied and numerous embodiments without departing from the scope of the invention.

An element is considered as being mounted (or provided) “on” another element when mounted or provided) either directly on the referenced element or mounted (or provided) on other elements overlaying the referenced element. Throughout this disclosure, spatial terms such as “upper,” “lower,” “above” and “below” (for example) are used for convenience in describing various elements or portions or regions of the elements as shown in the figures. These terms do not, however, require that the structure be maintained in any particular orientation.

Well-known structures and processes are not described or illustrated in detail to avoid obscuring the present invention.

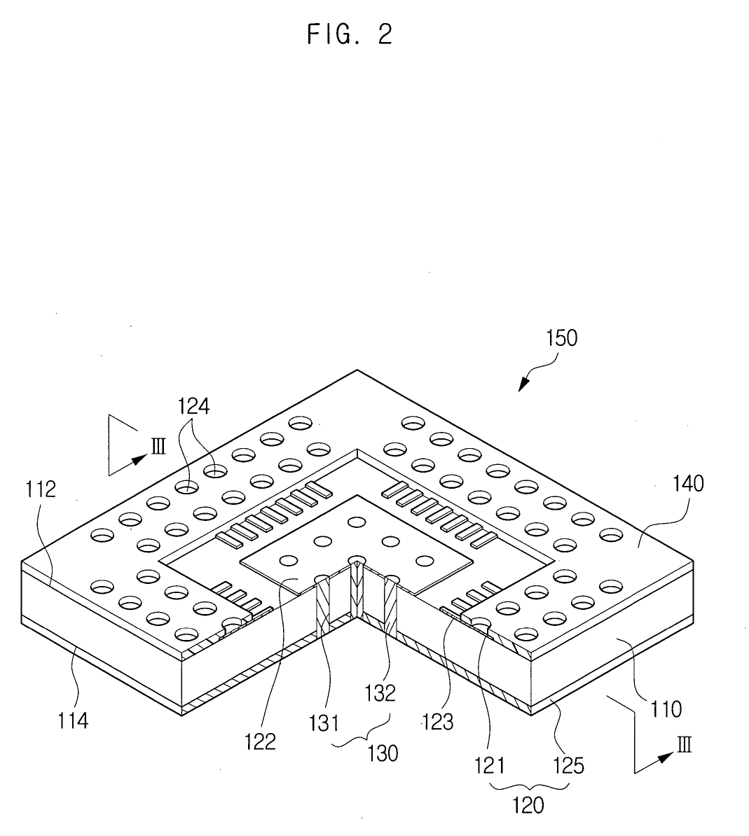

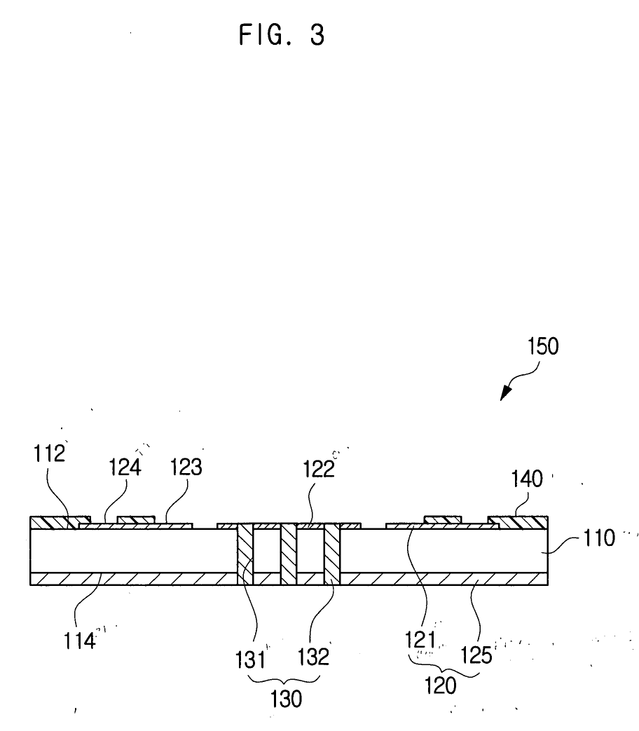

FIG. 2 is a perspective view of a wiring substrate 150 in accordance with an example, non-limiting embodiment of the present invention. FIG. 3 is a cross-sectional view taken along the line III-III of FIG. 2.

Referring to FIGS. 2 and 3, the wiring substrate 150 may include a substrate body 110 and a metal layer 120 may be provided on opposed surfaces of the wiring substrate 150.

By way of example only, the substrate body 110 may be an insulating plate having a predetermined thickness. The substrate body 110 may have a first (or upper) surface 112 and a second (or lower) surface 114 opposite to the first surface 112. The first surface 112 may support a chip mounting pad 122. A plurality of substrate pads 123 may be arranged around the chip mounting pad 122. A plurality of terminal pads 124 may be arranged along a peripheral region of the first surface 112. The terminal pads may be connected to the substrate pads 123. The substrate body 110 may be fabricated from one of prepreg, glass-epoxy resin, Bismaleimide-Triazine (BT) resin, polyimide, ceramic, and/or silicon, for example. The wiring substrate 150 may include a printed circuit board, a tape wiring substrate, a ceramic substrate, and/or a silicon substrate, for example.

The metal layer 120 may include a first (or upper) metal layer 121 provided on the first surface 112 and a second (or lower) metal layer 125 provided on the second surface 114. The first metal layer 121 may serve as a wiring layer inclusive of the chip mounting pad 122, the substrate pads and the terminal pads 124. The second metal layer 125 may serve as a heat radiating layer. By way of example only, the thickness of the heat radiating layer 125 may be equal to that of the wiring layer 121, or be larger than that of the wiring layer 121. In alternative embodiments, the heat radiating layer 125 may be thinner than the wiring layer 121. The heat radiating layer 125 may have a uniform thickness (as shown) or a varied thickness. By way of example only, the metal layer 120 may be formed by patterning and/or plating a Cu foil on the first and the second surfaces 112 and 114 of the substrate body 110. Numerous and alternative materials (instead of Cu) and techniques (other than patterning and plating), which are well known in this art, may be suitably implemented to provide the metal layer 120.

A plurality of heat conductive elements 130 may penetrate through the substrate body 110 to connect the chip mounting pad 122 to the heat radiating layer 125. For example, a plurality of through holes 131 may be provided in the substrate body 110. A Cu plating layer may be provided on the inner walls of the through holes 131. A heat conductive material 132 may be provided in the through holes 131. The heat conductive material 132 may be a low-melting-point material which may have good heat conductivity. By way of example only, the heat conductive material 132 may be a metal. The plating layer may be fabricated from numerous and alternative materials (other than Cu), and the heat conductive material 132 may be numerous and alternative materials (other than a metal).

By way of example only, the heat conductive elements 130 may be uniformly arranged in the chip mounting pad 122. The heat conductive elements 130 may have a cylindrical shape, for example. In alternative embodiments, the heat conductive elements 130 may be spaced apart in a non-uniform fashion. In alternative embodiments, the heat conductive elements 130 may have any geometric shape. The heat conductive elements 130 of a given wiring substrate 150 may have varied shapes.

A protective layer, for example a solder mask 140, may be provided on the first surface 112. The chip mounting pad 122, the substrate pads 123 and the terminal pads 124 may be exposed through the solder mask 140. The solder mask 140 may protect the wiring layer 121 from the external environment, for example. This example embodiment may include solder mask define type terminal pads 124. In alternative embodiments, the terminal pads 124 may be of a nonsolder mask define type.

By way of example only, the solder mask 140 may be formed by coating a photo solder resist on the first surface 112 and patterning the photo solder resist to expose the chip mounting pad 122, the substrate pads 123 and the terminal pads 124. An oxidation preventive metal may be provided on the chip mounting pad 122, the substrate pads 123, the terminal pads 124, and the heat radiating layer 125. The oxidation preventive metal may be gold and/or nickel, for example.

In this example embodiment, the metal layer 120 may be provided on two surfaces of the substrate body 110. In alternative embodiments, the metal layer 120 may include (in addition to the metal layer 121 and the metal layer 125) at least one internal metal layer provided in the substrate body 110. The internal metal layer may serve as an internal wiring layer, such as a ground layer and/or a power layer, for example. The internal metal layer may be connected to the substrate pads and terminal pads. The internal metal layer as the ground layer may be connected to the heat conductive elements and to the heat radiating layer. A wiring substrate may be fabricated by stacking a plurality of unit substrates having a metal layer provided on one or two surfaces of a substrate body. The wiring substrate may have a heat radiating layer provided on the second surface.

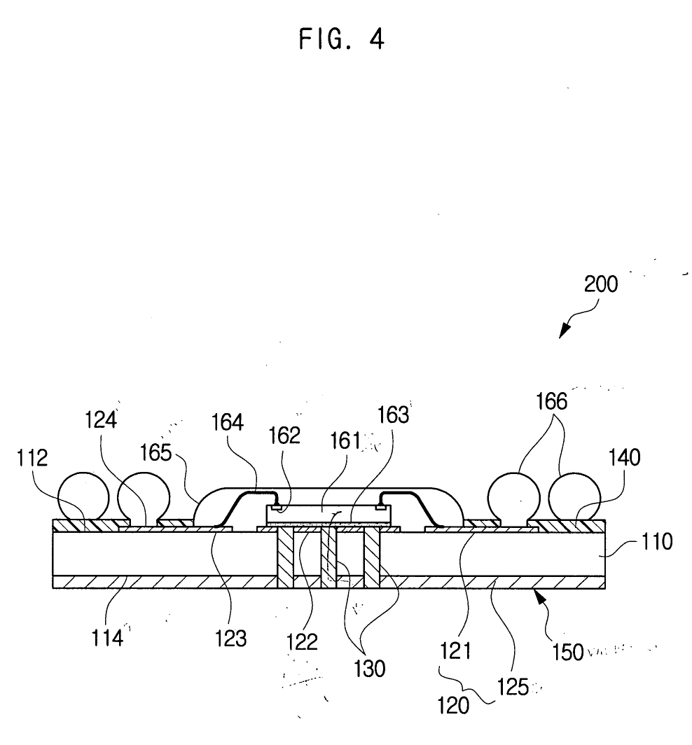

FIG. 4 is a cross-sectional view of a semiconductor package 200 implementing the wiring substrate 150 in accordance with an example, non-limiting embodiment of the present invention.

Referring to FIG. 4, the semiconductor package 200 may be a BGA semiconductor package having solder bumps 166 (for example) as external connection terminals. A semiconductor chip 161 may be provided on the chip mounting pad 122 of the wiring substrate 150 via an adhesive 163, for example. The semiconductor chip 161 may have an active surface supporting chip pads 162. In this example embodiment, the chip pads 162 may be arranged along a peripheral region of the active surface. In alternative embodiments, the chip pads 162 may be arranged in a central region of the active surface. By way of example only, bonding wires 164 may electrically connect the chip pads 162 to the substrate pads 123. An encapsulant 165 may protect and/or seal the semiconductor chip 161, the bonding wires 164, and the substrate pads 123 from the external environment, for example. The solder bumps 166 may be provided on the terminal pads 124.

The adhesive 163 may include a non heat-conductive adhesive and a heat-conductive adhesive. The heat-conductive adhesive may be used to facilitate heat transfer to the chip mounting pad 122.

The height of the bonding wires 164 may be reduced for a reduced height of the encapsulant 165. The bonding wires 164 may include a ball bonding type and a wedge bonding type, for example. The bonding wires 164 may be provided via a reverse wire bonding method and/or a bump reverse wire bonding method, for example.

The encapsulant 165 may be fabricated from a liquid epoxy molding compound, for example. The encapsulant may be fabricated from numerous and alternative materials that are well known in this art. The encapsulant 165 may be provided via a transfer molding method or a potting method, for example.

By way of example only, the solder bumps 166 may be provided by applying a flux on the terminal pads 124, and providing and reflowing solder bumps. The solder bumps 166 may be replaced with Au and/or Ni bumps, for example. The solder bumps 166 may project further from the first surface 112 than the encapsulant 165.

The semiconductor package 200 may have the heat radiating layer 125 provided on the second surface 114 of the wiring substrate 150, thereby eliminating the need for an additional heat spreader. Notwithstanding, in alternative embodiments, an additional heat spreader may be implemented.

Heat may transfer through the semiconductor package 200 as follows. Heat generated during a chip operation may be transmitted from the semiconductor chip 161, through the adhesive 163 and to the chip mounting pad 122. The heat in the chip mounting pad 122 may be transmitted through the heat conductive elements 130, to the radiating layer 125, and radiated to the external environment from the radiating layer 125. When the semiconductor package 200 is mounted on a motherboard (for example) via the solder bumps 166), the heat may be effectively radiated from the heat radiating layer 125, because the heat radiating layer 125 may face away from the motherboard and may be exposed to the air.

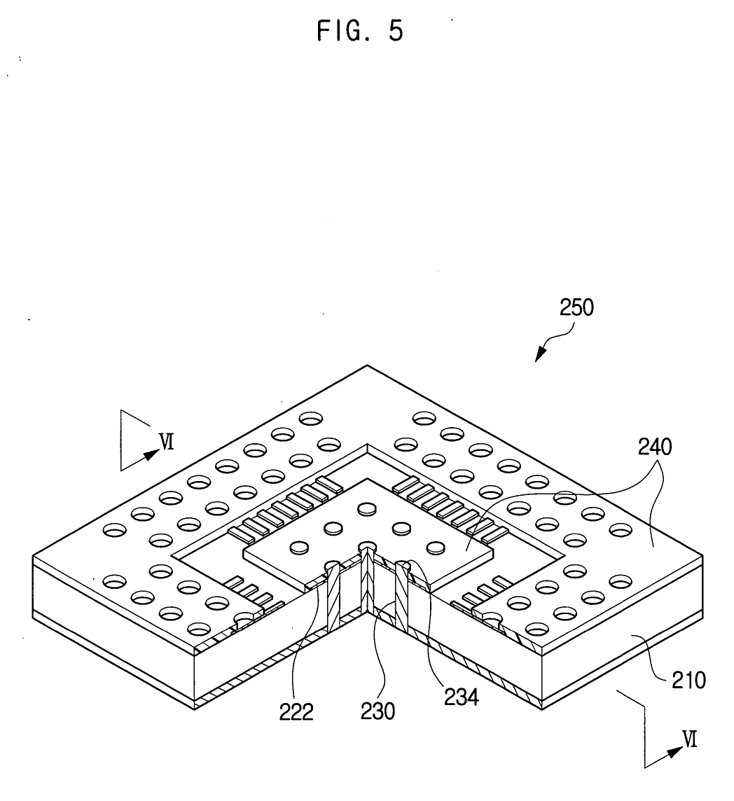

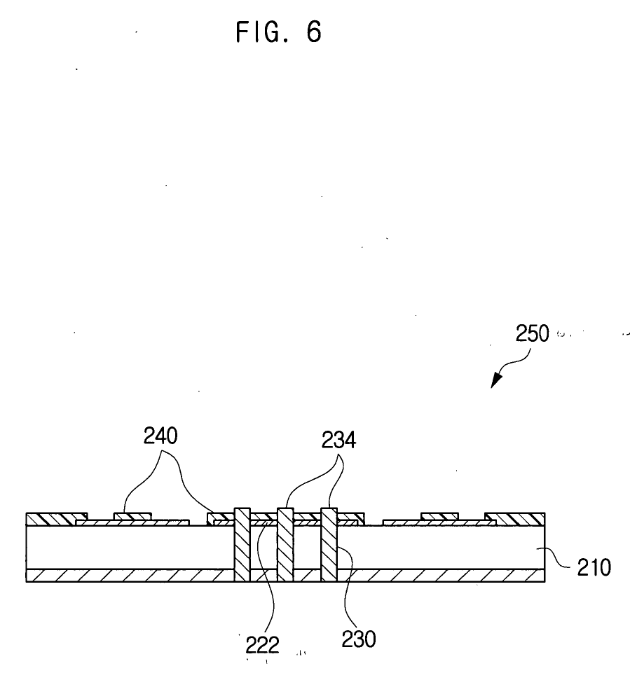

In this example embodiment, heat may be transmitted from the semiconductor chip 161, through the adhesive 163, and to the chip mounting pad 122. As shown in FIGS. 5 and 6, heat may be directly transmitted from the semiconductor chip to the chip mounting area using metal protrusions.

FIG. 5 is a perspective view of a wiring substrate 250 in accordance with another example, non-limiting embodiment of the present invention. FIG. 6 is a cross-sectional view taken along the line VI-VI of FIG. 5.

Referring to FIGS. 5 and 6, the wiring substrate 250 may have metal protrusions 234 that extend upward from a chip mounting pad 222. In all other respects, the wiring substrate 250 may have the same structure as the wiring substrate 150. Example, non-limiting metal protrusions 234 are described below.

The metal protrusions 234 may correspond to the heat conductive elements 230. For example, as shown, the metal protrusions 234 may be uniformly arranged in the chip mounting pad 222. The metal protrusions 234 may be fabricated using conventional bump forming techniques that are well known in this art. The metal protrusions 234 may be formed while forming the heat conductive elements 230, for example by extending the tops of the heat conductive elements 230 upward and beyond the upper surface of the chip mounting pad 222.

In this example embodiment, the chip mounting area 222 may be covered with a solder mask 240. In alternative embodiments, the chip mounting pad 222 may be exposed in the same manner as the chip mounting pad 122 (see FIG. 3).

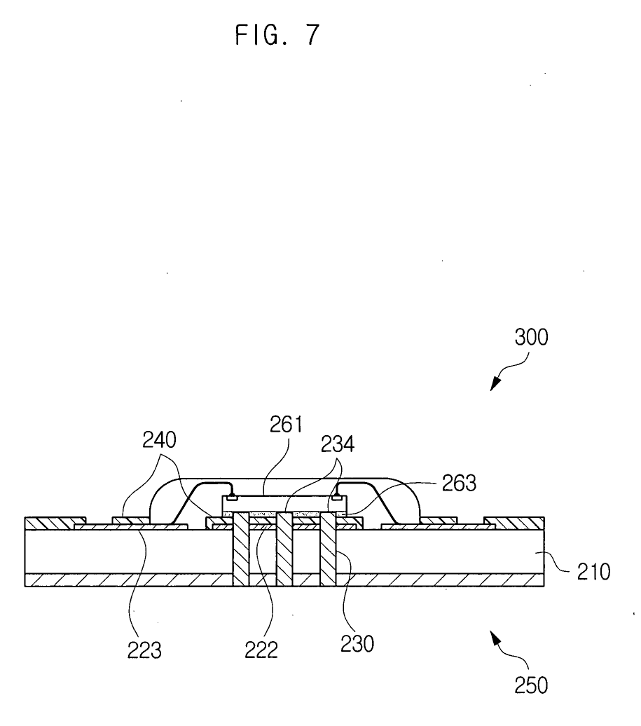

FIG. 7 is a cross-sectional view of a semiconductor package 300 implementing the wiring substrate 250 in accordance with another example, non-limiting embodiment of the present invention.

Referring to FIG. 7, the semiconductor package 300 may have the same structure as the semiconductor package 200, except that a semiconductor chip 261 may mechanically contact the metal protrusions 234. The semiconductor chip 261 may be attached to a chip mounting pad 222 of a wiring substrate 250 using an adhesive 263.

The metal protrusions 234 connected to the heat conductive elements 230 may directly contact the semiconductor chip 261, thereby promptly radiating the heat of the semiconductor chip 261.

The metal protrusions 234 may impede the flow of adhesive 263 when the semiconductor chip 261 is mounted on the wiring substrate 250. This may reduce the likelihood that the adhesive 263 may invade the active surface of the semiconductor chip 261 and/or flow onto unintended portions of the upper surface of the wiring substrate 250 (e.g., the substrate pads 223).

The height of the metal protrusions 234 may be determined in consideration of the height of the semiconductor chip 261 mounted on the solder mask 240.

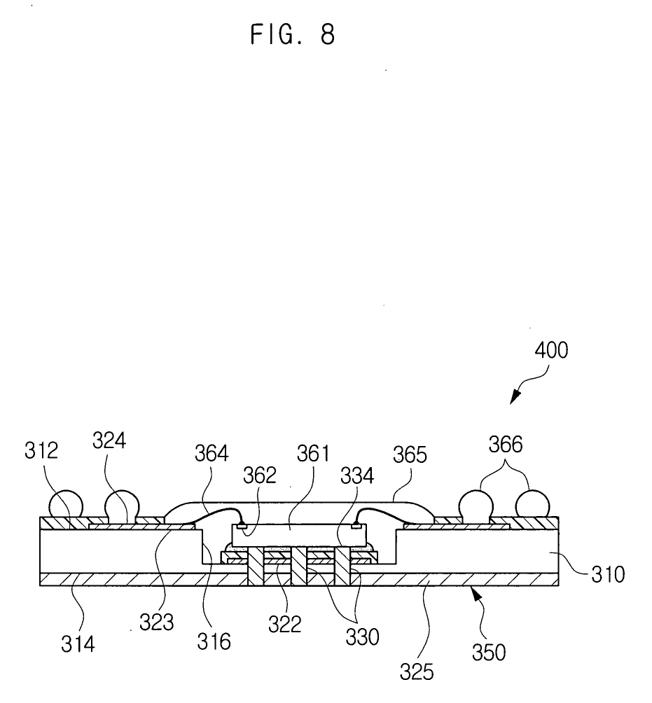

FIG. 8 is a cross-sectional view of a semiconductor package 400 implementing a wiring substrate 350 in accordance with another example, non-limiting embodiment of the present invention.

The wiring substrate 350 may have a recess 316 provided in a first surface 312 of a substrate body 310. A chip mounting pad 322 may be provided in the recess 316. The chip mounting pad 322 may be connected to a heat radiating layer 325 on a second surface 314 via heat conducting elements 330.

The semiconductor package 400 may include the wiring substrate 350 and a semiconductor chip 361 mounted on the chip mounting pad 322 in the recess 316. Bonding wires 364 may electrically connect chip pads 362 of the semiconductor chip 361 to substrate pads 323 of the wiring substrate 350. An encapsulant 365 may protect and/or seal the semiconductor chip 361, the bonding wires 364 and the substrate pads 323 from the external environment, for example. Solder bumps 366 may be provided on terminal pads 324 around the encapsulant 365.

The recess 316 provided in the wiring substrate 350 may allow fine pitched solder bumps 366. For example, the semiconductor chip 361 may be provided on the bottom surface of the recess 316, so that the bonding wires 364 may have a reduced height. The encapsulant 365 may have a reduced height, accordingly. Thereby the size of the solder bumps 366 may be reduced, thereby allowing finer pitched solder balls 366 to be implemented.

The chip mounting pad 322 may be connected to the heat radiating layer 325 through the heat conducting elements 330. Therefore, the semiconductor package 400 may have a heat radiation effect similar to the previous example embodiments.

Although example, non-limiting embodiments of the present invention have been described in detail, it will be understood that many variations and/or modifications of the basic inventive concepts, which may appear to those skilled in the art, will still fall within the spirit and scope of the example embodiments of the present invention as defined in the appended claims.

What is claimed is:

1. A wiring substrate comprising:
a substrate body having a first surface and a second surface opposite to the first surface;
a metal wiring layer provided on the first surface of the substrate body, the metal wiring layer having a chip mounting pad, a plurality of substrate pads, and a plurality of terminal pads connected to the substrate pads; and
a metal heat radiating layer provided on the second surface of the substrate body; and
a plurality of heat conducting elements penetrating the substrate body to connect the chip mounting pad to the heat radiating layer.

2. The wiring substrate of claim 1, wherein the heat conducting elements include a thermal conductive material filled in through holes of the substrate body.

3. The wiring substrate of claim 2, wherein the heat conducting elements are uniformly arranged in the chip mounting pad.

4. The wiring substrate of claim 3, further including metal protrusions extended from the chip mounting pad.

5. The wiring substrate of claim 4, wherein the metal protrusions correspond to the heat conducting elements.

6. The wiring substrate of claim 3, wherein the heat conducting elements extend from the chip mounting pad.

7. The wiring substrate of claim 2, wherein the chip mounting pad is provided in a recess provided in the first surface of the substrate body.

8. The wiring substrate of claim 1, wherein the substrate body is fabricated from prepreg, glass-epoxy resin, BT resin, polyimide, ceramic and silicon.

9. A semiconductor package comprising:
a semiconductor chip having an active surface supporting a plurality of chip pads;
a wiring substrate including
a substrate body having a first surface and a second surface opposite to the first surface,
a metal wiring layer provided on the first surface of the substrate body, the metal wiring layer having a chip mounting pad, a plurality of substrate pads, and a plurality of terminal pads connected to the substrate pads,
a metal heat radiating layer provided on the second surface of the substrate body, and
a plurality of heat conducting elements penetrating the substrate body to connect the chip mounting pad to the heat radiating layer;
bonding wires electrically connecting the semiconductor chip to the wiring substrate;
an encapsulant sealing the semiconductor chip and the bonding wires; and
external connection terminals provided on the terminal pads.

10. The package of claim 9, wherein the heat conducting elements include a thermal conductive material filled in through holes of the substrate body.

11. The package of claim 10, wherein the heat conducting elements are uniformly arranged in the chip mounting pad.

12. The package of claim 11, further including metal protrusions extended from the chip mounting pad.

13. The package of claim 12, wherein the metal protrusions correspond to the heat conducting elements.

14. The package of claim 11, wherein the heat conducting elements extend from the chip mounting pad.

15. The package of claim 10, wherein the chip mounting pad is provided in a recess provided in the first surface of the substrate body.

16. The package of claim 9, wherein the wiring substrate is one of a printed circuit board, a tape wiring substrate, a ceramic substrate and a silicon substrate.

17. A semiconductor package comprising:
a semiconductor chip;
a wiring substrate having a first surface including a chip mounting pad on which the semiconductor chip is provided, a second surface having a heat radiating layer, and heat conducting elements extending between the heat radiating layer and the semiconductor chip; and
external connection terminals provided on the first surface of the wiring substrate.

18. The package of claim 17, wherein the heat conducting elements are uniformly arranged in the chip mounting pad.

19. The package of claim 17, wherein the heat conducting elements extend the shortest distance between the semiconductor chip and the heat radiating layer.

20. The package of claim 19, wherein the heat conducting elements are in contact with the semiconductor chip.

21. The package of claim 17, wherein the semiconductor chip is provided in a recess provided in the first surface of the wiring substrate.
